(19) United States
(12) Patent Application Publication
(10) Pub. No.: US 2024/0278213 A1
(43) Pub. Date: Aug. 22, 2024

(54) PHOTOCATALYTIC LAYER ARRANGEMENT AND METHOD FOR PRODUCING SUCH A LAYER ARRANGEMENT

(71) Applicant: DR. JOHANNES HEIDENHAIN GmbH, Traunreut (DE)

(72) Inventors: Peter SPECKBACHER, Kirchweidach (DE); Wolfgang SEDLMEIER, Obing (DE); Martina DOWY, Rosenheim (DE); Réka CSIKI, Traunstein (DE); Bernhard WUNDERLICH, München (DE)

(21) Appl. No.: 18/693,297

(22) PCT Filed: Jul. 29, 2022
(86) PCT No.: PCT/EP2022/071310

§ 371 Date: Mar. 19, 2024

(30) Foreign Application Priority Data
Sep. 24, 2021 (DE) 10 2021 210 660.9

(51) Int. Cl. B01J 21/06; B01J 23/26; B01J 35/30; B01J 35/39; B01J 35/40; B01J 37/02; B01J 37/34; C03C 17/36; C23C 14/00; C23C 14/08

(52) U.S. Cl. CPC B01J 21/063; B01J 23/26; B01J 35/39; B01J 35/393; B01J 35/40; B01J 37/0228; B01J 37/0244; B01J 37/347; C03C 17/3605; C03C 17/3649; C23C 14/0057; C23C 14/083; C03C 2218/155

(57) ABSTRACT

A photocatalytic layer arrangement includes a carrier substrate on which a chromium layer with a defined nitrogen content is deposited. A titanium oxide layer having the formula TiOₓ (x=2-4) is grown on the chromium layer, and the anatase phase of the titanium oxide layer with respect to the rutile phase of the titanium oxide layer has a percentage in the range of 30%-90%.

### FIELD OF THE INVENTION

The present invention relates to a photocatalytic layer arrangement and a method for producing such a layer arrangement.

### BACKGROUND INFORMATION

Photocatalytically active layers are sometimes required in optical analysis methods for examining material samples consisting of biological molecules. UV irradiation can be used to remove process residues from such layers, for example, or to selectively activate the surface of certain regions of the layers. In this context, photocatalytic activity means that irradiation with electromagnetic radiation—such as light in a suitable wavelength range—can trigger a specific chemical reaction in the corresponding material. A photocatalytically active material suitable for this purpose is titanium oxide, which can be available in several crystal structures or phases. The so-called anatase phase and the rutile phase of titanium oxide are primarily used in this context, in which the anatase phase shows a significantly higher photocatalytic activity and is thus particularly suitable for photocatalytic applications.

German Patent Document No. 10 2011 083 054 describes a photocatalytic layer arrangement in which a photocatalytic layer of one or more metal oxides is applied to a metallic adhesion promoter layer which is applied to a substrate. Among other materials, the anatase phase of titanium dioxide is described as the material for the photocatalytic layer, while chromium, for example, is mentioned alongside other metals for the adhesion promoter layer. Specific measures for optimizing the layer arrangement for the analysis of biomolecules are not provided in German Patent Document No. 10 2011 083 054.

### SUMMARY

Example embodiments of the present invention provide a photocatalytic layer arrangement which ensures a high photocatalytic activity of the titanium oxide layer used therein and provides a suitable surface for the deposition of biomolecules. Furthermore, a suitable production method for such a layer arrangement is provided.

According to example embodiments of the present invention, photocatalytic layer arrangement has a carrier substrate onto which a deposited chromium layer having a defined nitrogen content is arranged. A grown titanium oxide layer having the formula TiOₓ (x=2-4) is arranged on the chromium layer, in which the anatase phase of the titanium oxide layer with respect to the rutile phase of the titanium oxide layer has a percentage in the range of 30%-90%.

For example, the anatase phase of the titanium oxide layer with respect to the rutile phase of the titanium oxide layer has a percentage in the range of 50%-80%.

It is possible that the titanium oxide layer has a layer thickness in the range of 30 nm-300 nm.

For example, it is provided that the titanium oxide layer has a granular surface structure with crystallites with a size in the range of 20 nm-120 nm.

The anatase crystallites in the titanium oxide layer can have a substructure.

Furthermore, the chromium layer can have a layer thickness in the range of 30 nm-150 nm.

It is also possible that the chromium layer has a nitrogen content in the range of 15 at %-25 at %.

It can be provided that the chromium layer has a nitrogen content in the range of 15 at %-25 at % at least to a depth of 10 nm.

For example, the carrier substrate is formed from glass.

According to example embodiments of the present invention, a method for producing a photocatalytic layer arrangement includes: providing a carrier substrate; applying a chromium layer with a defined nitrogen content to the carrier substrate using a reactive sputtering method; and depositing a titanium oxide layer having the formula TiOₓ (x=2-4) on the chromium layer using a low-temperature sputtering method, in which a titanium oxide layer grows during deposition, the anatase phase of which with respect to the rutile phase has a percentage in the range of 30%-90%.

The chromium layer can be applied with a nitrogen content in the range of 15 at %-25 at %, in which the nitrogen is contained near the surface in the chromium layer at least to a depth of 10 nm.

For example, the chromium layer is applied using a reactive sputtering method with an argon-nitrogen flow ratio of Ar (sccm)/N₂ (sccm)=1.0-2.0.

Furthermore, it can be provided that the chromium layer is applied with a layer thickness in the range of 30 nm-150 nm.

It is also possible for the titanium oxide layer to be deposited with a layer thickness in the range of 30 nm-300 nm.

For example, the titanium oxide layer is deposited with a granular surface structure which has anatase crystallites in the size range 20 nm-120 nm.

In the photocatalytic layer arrangement described herein and the corresponding method described herein, the deposited titanium oxide layer possesses particularly good photocatalytic properties. This is guaranteed immediately after deposition, without the need for a further process step such as tempering. Furthermore, the enlarged active surface of the titanium oxide layer formed ensures particularly good accumulation of biomolecules.

Further details and aspects of example embodiments of the present invention are explained in more detail below with reference to the appended schematic Figures.

### BRIEF DESCRIPTION OF THE DRAWINGS

FIG. 1 is a cross-sectional view of a layer arrangement according to an example embodiment of the present invention.

FIG. 2 illustrates the measurement curve of an X-ray diffractometry examination of the layer arrangement, with the marked main peaks for the anatase and rutile phase of the titanium dioxide layer.

FIGS. 3a-3c are scanning electron microscope images of the surface of a titanium oxide layer with different proportions of the crystalline anatase phase.

### DETAILED DESCRIPTION

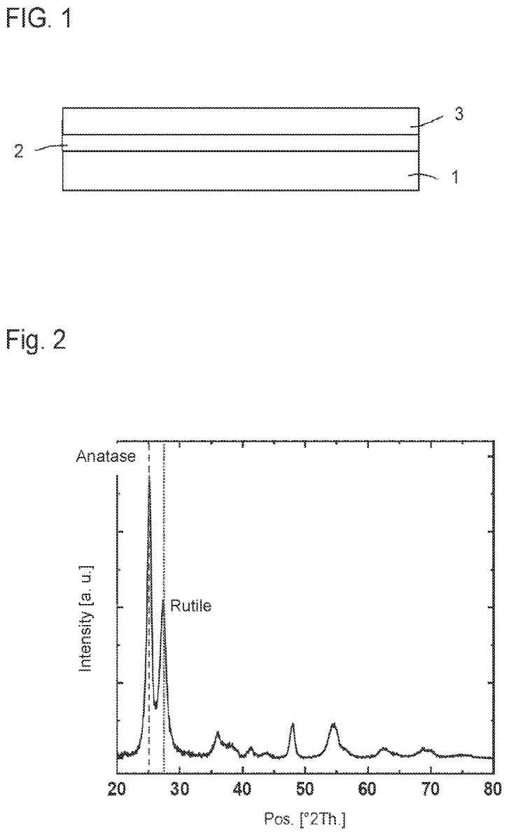

FIG. 1 is a cross-sectional sectional view of a photocatalytic layer arrangement according to an example embodiment of the present invention. The layer arrangement includes a carrier substrate 1 on which a chromium layer 2 with a defined nitrogen content is deposited. On top of the chromium layer 2 is a grown, photocatalytically active titanium oxide layer 3 having the formula TiOₓ, in which wherein x=2-4. The following description provides further details of the chromium layer 2 and the titanium oxide layer 3.

Such a layer arrangement can be used, for example, in optical sensors for examining material samples including or consisting of biological molecules—hereinafter referred to as biomolecules. For this purpose, the properties of the photocatalytically active titanium oxide layer 3 are decisive.

This layer has a high thermal, mechanical, and chemical stability and is also biocompatible. This makes the titanium oxide layer 3 particularly suitable for the accumulation—in the form of non-specific non-covalent (physical) bonds—of biomolecules, since titanium oxide provides for good electrostatic interaction. In addition, irradiation of the photocatalytically active titanium oxide layer 3 with a suitable UV source in the wavelength range of 200 nm-400 nm can be used to clean the surface of the layer and/or to activate the surface. Photocatalysis results in bond-destroying effects, whereby organic compounds, such as carbon compounds C—C, C—H, etc., are broken down and a partial oxidation of the surface residues takes place with the formation of carbon oxides Cₒₓ. The granular or rough structure of the surface of the titanium oxide layer 3, which structure will be described in more detail below, additionally results in a significant increase in the active surface area. This provides for improved accumulation of biomolecules and enhances the photocatalytic properties.

In addition, the layer arrangement that includes the titanium oxide layer 3 and the reflective chromium layer 2 can be used to generate a localized field superelevation in the region of the surface of the titanium oxide layer 3 with fluorescence excitation at a suitable wavelength. This increases the signal yield, for example, with fluorescence detection of biomolecules accumulated on the surface being provided in a corresponding optical sensor. To maximize the detection effect, the layer thickness of the titanium oxide layer 3 and the excitation wavelength used can be matched to each other.

To produce the photocatalytic layer arrangement described herein, a chromium layer 2 having a defined nitrogen content is first deposited on the carrier substrate 1. The nitrogen-enriched chromium layer 2 serves as an intermediate layer for the titanium oxide layer 3 that grows subsequently.

The material for the carrier substrate 1 is, for example, glass, e.g., glass types D263 or BF33 or quartz glass are suitable. Alternatively, the use of glass ceramics such as Zerodur are also possible. Similarly, suitable optically transparent crystals such as zinc selenide (ZnSe) or potassium bromide (KBr) could be used as material for the carrier substrate 1, which would have to be provided in a suitable plate-like or planar form. For example, the corresponding carrier substrate material has the lowest possible autofluorescence.

The nitrogen-enriched chromium layer 2 is deposited using a reactive sputtering method with an argon-nitrogen flow ratio of Ar (sccm)/N₂ (sccm)=1.0-2.0, e.g., an argon-nitrogen flow ratio of Ar (sccm)/N₂ (sccm)=1.2-1.7. Suitable layer thicknesses for the chromium layer 2 are in the range of 30 nm-150 nm.

A certain nitrogen content in the chromium layer 2 is provided for the subsequent growth of the particularly strongly photocatalytically active anatase-rich phase of the titanium oxide layer 3. The chromium layer 2 thus induces titanium oxide growth with a defined phase mixture of the anatase phase and the rutile phase of the titanium oxide. This phase mixture can have improved photocatalytic properties compared to a pure anatase phase due to charge carrier processes. The nitrogen content in the chromium layer 2 should be in the range of, for example, 15 at %-25 at %, in which the nitrogen content is decisive above all near the surface in relation to the boundary surface to the titanium oxide layer 3, e.g., to a depth of at least 10 nm in the chromium layer 2. The chromium layer 2 enriched with nitrogen in this manner acts as a growth enhancer for the anatase phase of the titanium oxide layer 3 growing thereabove with its good photocatalytic properties.

For example, the chromium layer 2 promotes the growth of the anatase phase of the titanium oxide layer 3.

Using a low-temperature sputtering process, the titanium oxide layer 3 is deposited on a chromium layer 2 formed in this manner, in which the following applies with regard to the composition of the titanium oxide layer 3: x=2-4 for TiOₓ.

Typical layer thicknesses for the chromium layer 3 are in the range of 30 nm-300 nm.

The anatase phase of the titanium oxide layer 3, for example, grows during deposition without the need for further processing steps such as tempering, etc. The titanium oxide shows stem growth perpendicular to the chromium layer 2, which is typical for sputtering processes. The anatase phase of the titanium oxide layer 3 with respect to the rutile phase of the titanium oxide layer 3 as determined by X-ray diffractometry has a percentage in the range of 30%-90% in a region close to the surface, typically less than 100 nm, e.g., a percentage in the region of 50%-80%. The amorphous titanium oxide content in the titanium oxide layer 3 is not taken into account in this regard.

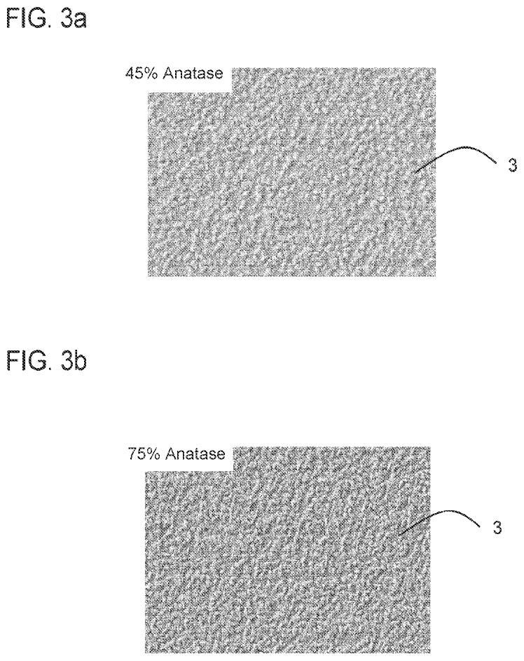

FIG. 2 illustrates an exemplary measurement curve for regions near the surface of such titanium oxide layers by X-ray diffraction at a constant angle of incidence Omega=0.3°, which typically corresponds to a penetration depth of less than 100 nm. The significantly high percentage of the anatase phase (first peak on the left) with respect to the rutile phase (second peak on the left) in the titanium oxide layer is discernable.

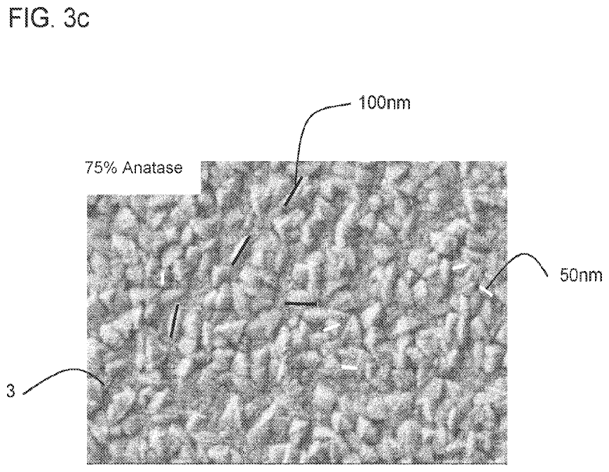

The titanium oxide layer grown in this manner also has a granular or rough surface structure, which shows a plurality of crystallites forming. The higher the proportion of the anatase phase in the titanium oxide layer, the greater the degree of coverage of the surface of the titanium oxide layer with such crystallites. This can be seen from the comparison of the two images from the scanning electron microscope in FIGS. 3a and 3b, which are images of corresponding surfaces of titanium oxide layers 3. In FIG. 3a, the corresponding titanium oxide layer 3 has an anatase content of approximately 45%, and, in FIG. 3b, the corresponding titanium oxide layer 3 has an anatase content of approximately 75%.

The image from the scanning electron microscope shown in FIG. 3c is a further enlarged partial view of the layer surface shown in FIG. 3b, which illustrates that the crystallites of the anatase phase forming in the titanium oxide layer 3 have a substructure in the form of a disk structure. For titanium oxide layers with a sufficiently large anatase content, the anatase crystallites have sizes in the range of 20 nm-120 nm, e.g., 30 nm-100 nm. In FIG. 3c, a plurality of crystallites are characterized by corresponding straight line segments, which have a size of 50 nm (white segments) or 100 nm (black segments). Such rough surfaces of the titanium oxide layer 3 are considered to be advantageous, since the active surface area thereabove is significantly enlarged, resulting in improved accumulation of biomolecules and improved photocatalytic properties.

1-15. (canceled)

16. A photocatalytic layer arrangement, comprising:
a carrier substrate;
a chromium layer having a defined nitrogen content arranged on the carrier substrate; and
a titanium oxide layer having the formula TiOₓ(x=2-4) arranged on the chromium layer;
wherein an anatase phase of the titanium oxide layer with respect to a rutile phase of the titanium oxide layer has a percentage between 30% and 90%.

17. The photocatalytic layer arrangement according to claim 16, wherein the chromium layer is arranged as a deposited layer on the carrier substrate.

18. The photocatalytic layer arrangement according to claim 16, wherein the titanium oxide layer is arranged as a grown layer on the chromium layer.

19. The photocatalytic layer arrangement according to claim 16, wherein the anatase phase of the titanium oxide layer with respect to the rutile phase of the titanium oxide layer has a percentage between 50% and 80%.

20. The photocatalytic layer arrangement according to claim 16, wherein a layer thickness of the titanium oxide layer is between 30 nm and 300 nm.

21. The photocatalytic layer arrangement according to claim 16, wherein the titanium oxide layer has a granular surface structure with anatase crystallites in a size between 20 nm and 120 nm.

22. The photocatalytic layer arrangement according to claim 21, wherein the anatase crystallites in the titanium oxide layer have a substructure.

23. The photocatalytic layer arrangement according to claim 16, wherein a layer thickness of the chromium layer is between 30 nm and 150 nm.

24. The photocatalytic layer arrangement according to claim 16, wherein the nitrogen contents of the chromium layer is between 15 at % and 25 at %.

25. The photocatalytic layer arrangement according to claim 16, wherein the nitrogen content of the chromium layer is between 15 at % and 25 at % at least to a depth of 10 nm.

26. The photocatalytic layer arrangement according to claim 16, wherein the carrier substrate includes glass.

27. The photocatalytic layer arrangement according to claim 16, wherein the photocatalytic layer arrangement is arranged in an optical sensor adapted to examine samples that include biological molecules.

28. The photocatalytic layer arrangement according to claim 16, wherein the carrier substrate includes borosilicate glass and/or quartz glass.

29. The photocatalytic layer arrangement according to claim 16, wherein the carrier substrate includes a glass ceramic, zinc selenide, and/or potassium bromide.

30. A method for producing a photocatalytic layer arrangement, comprising:
applying a chromium layer having a defined nitrogen content to a carrier substrate using a reactive sputtering method; and
depositing a titanium oxide layer having the formula TiOₓ (x=2-4) on the chromium layer using a low-temperature sputtering method;
wherein a titanium oxide layer grows during the deposition, an anatase phase of the titanium oxide layer respect to an rutile phase of the titanium oxide layer has a percentage between 30% and 90%.

31. The method according to claim 30, wherein the nitrogen content of the chromium layer is between 15 at % and 25 at %, and the nitrogen is contained near a surface of the chromium layer at least to a depth of 10 nm.

32. The method according to claim 30, wherein the chromium layer is applied using the reactive sputtering method with an argon-nitrogen flow ratio that satisfies the following condition:Ar (sccm)/N₂ (sccm)=1.0 to 2.0.

33. The method according to claim 30, wherein a layer thickness of the chromium layer is between 30 nm and 150 nm.

34. The method according to claim 30, wherein a layer thickness of the titanium oxide layer is between 30 nm and 300 nm.

35. The method according to claim 30, wherein a granular surface structure of the titanium oxide layer includes anatase crystallites having a size between 20 nm and 120 nm.
